(19) United States
(12) Patent Application Publication
(10) Pub. No.: US 2009/0061622 A1
(43) Pub. Date: Mar. 5, 2009

(54) METHOD FOR MANUFACTURING SEMICONDUCTOR DEVICE CAPABLE OF PREVENTING LIFTING OF AMORPHOUS CARBON LAYER FOR HARD MASK

(76) Inventors: Sang Tae AHN, Gyeonggi-do (KR); Ja Chun KU, Gyeonggi-do (KR); Eun Jeong KIM, Jeollanam-do (KR)

Correspondence Address: LADAS & PARRY LLP, 224 SOUTH MICHIGAN AVENUE, SUITE 1600, CHICAGO, IL, 60604, US

(21) Appl. No.: 12/045,174

(22) Filed: Mar. 10, 2008

(30) Foreign Application Priority Data
Aug. 31, 2007 (KR) 10-2007-0088382

(51) Int. Cl. H01L 21/44

(52) U.S. Cl. 438/656; 257/E21.476

(57) ABSTRACT

In a method for manufacturing a semiconductor device, a conductive layer is formed on a semiconductor substrate. A surface of the conductive layer is then treated by plasma. After the conductive layer is treated, an amorphous carbon layer for a hard mask is formed on the surface of the conductive layer that has been treated by the plasma.

### CROSS-REFERENCE TO RELATED APPLICATIONS

The present application claims priority to Korean patent application number 10-2007-0088382 filed on Aug. 31, 2007, which is incorporated herein by reference in its entirety.

### BACKGROUND OF THE INVENTION

The present invention relates to a method for manufacturing a semiconductor device, and more particularly, to a method for manufacturing a semiconductor device which prevents the lifting of an amorphous carbon layer for a hard mask.

Semiconductor devices have rapidly proceeded towards high levels of integration as semiconductor manufacturing technologies have continued to develop. As the level of integration increases, the critical dimensions of patterns formed in the semiconductor devices and the widths between these patterns become fine.

In general, a photoresist pattern is formed on a layer that is to be etched using a photolithographic process. The layer to be etched is then etched using the photoresist pattern as an etch mask; and accordingly, a fine pattern is formed in the semiconductor device.

The photolithographic process is implemented as follows: a pattern is exposed on a photoresist using KrF or ArF; a development process then follows; and thus a photoresist pattern is formed. The height of a pattern increases with the increased level of integration of the semiconductor device. However, when ArF is used for the exposure, it is difficult to form a fine pattern due to optical factors resulting from the short wavelength of ArF and chemical factors resulting from the use of a chemical amplification-type resist.

Under these circumstances, in order to form a fine pattern, a hard mask having a hard physical characteristic has been used together with the photoresist pattern when manufacturing a semiconductor device. The hard mask is used in nearly all processes for forming patterns in semiconductor devices, including processes such as an insulation layer patterning process and a metal line forming process. An amorphous carbon layer is an example of a hard mask used in the pattern forming processes.

The amorphous carbon layer for a hard mask can be formed to have various properties, and during the manufacturing process of a semiconductor device, the hard mask is used selectively in consideration of the absorption coefficient and/or etching selectivity.

In further detail, the amorphous carbon layer is used in a process for forming a device isolation structure and in a process for forming bit lines when a semiconductor device is manufactured. During these processes, the properties of the amorphous carbon layer must be such that the amorphous carbon layer has excellent etching selectivity with respect to the layer to be etched while having a small thickness, and the amorphous carbon layer also must be suitable for a high temperature process over 550° C.

Further, the amorphous carbon layer is used in a process for forming storage node contacts and a process for forming metal lines when a semiconductor device is manufactured. During these processes, while the properties of the amorphous carbon layer must be such that the etching selectivity of the amorphous carbon layer is lower than that of a layer to be etched, the properties of the amorphous carbon layer must also be such that the amorphous carbon layer has a low absorption coefficient to allow for excellent alignment characteristics during the photolithographic process. Also, the amorphous carbon layer must be suitable for a low temperature process around 300° C.

As the design rule of a semiconductor device gradually decreases the line width of metal lines in the semiconductor device decrease; and accordingly, the amorphous carbon layer is necessarily used in a patterning process for forming metal lines using aluminum to have a line width below 60 nm.

The amorphous carbon layer used in the patterning process of forming the metal lines using aluminum must be suitable for a temperature below 400° C. This is because the amorphous carbon layer must have an excellent alignment characteristic in the process for forming the metal lines using aluminum, and this aluminum process must be implemented at a temperature below 400° C.

However, the amorphous carbon layer for a hard mask has a different adhesion degree and Coefficient of Thermal Expansion (CTE) when compared to the conductive layer located thereunder, and thus the amorphous carbon layer is prone to lift resulting in the conductive layer being attacked.

### SUMMARY OF THE INVENTION

Embodiments of the present invention are directed to a method for manufacturing a semiconductor device which can prevent lifting of an amorphous carbon layer for a hard mask.

In one aspect, a method for manufacturing a semiconductor device comprises the steps of forming a conductive layer on a semiconductor substrate; treating the surface of the conductive layer by plasma; and forming an amorphous carbon layer for a hard mask on the surface of the conductive layer treated by the plasma.

The conductive layer can be made from Al or W.

The conductive layer comprises a barrier layer formed on the surface thereof.

The barrier layer can be made from a stack of Ti/TiN.

The step of treating the surface of the conductive layer by plasma and the step of forming the amorphous carbon layer are implemented in situ.

Plasma treatment is implemented using any one or both of O₂ and Ar gases.

In another aspect, a method for manufacturing a semiconductor device comprises the steps of forming a conductive layer on a semiconductor substrate; forming a buffer layer on the conductive layer; and forming an amorphous carbon layer for a hard mask on the buffer layer.

The conductive layer can be made from Al or W.

The conductive layer includes a barrier layer formed on a surface thereof.

The barrier layer can be made from a stack of Ti/TiN.

The buffer layer can be an oxide layer, a nitride layer, or a stack of an oxide layer and a nitride layer.

The oxide layer can be an undoped silicate glass (USG) layer.

The oxide layer is formed to have a thickness in the range of 50˜400 Å.

The nitride layer is formed to have a thickness in the range of 50˜200 Å.

### BRIEF DESCRIPTION OF THE DRAWINGS

FIGS. 1A and 1B are sectional views shown for explaining a method for manufacturing a semiconductor device capable of preventing lifting of an amorphous carbon layer for a hard mask in accordance with an embodiment of the present invention.

FIGS. 2A and 2B are sectional views shown for explaining a method for manufacturing a semiconductor device capable of preventing lifting of an amorphous carbon layer for a hard mask in accordance with another embodiment of the present invention.

### DESCRIPTION OF SPECIFIC EMBODIMENTS

In the present invention, in order to prevent lifting of an amorphous carbon layer hard mask formed on a conductive layer, the upper surface of the conductive layer is pretreated by plasma using O₂ and Ar gases before the amorphous carbon layer is formed.

Also, in the present invention, before the amorphous carbon layer for a hard mask is formed, a buffer layer that can be an oxide layer, a nitride layer, or an oxide layer/nitride layer stack can be formed on the conductive layer.

Under these circumstances, stresses in the amorphous carbon layer and the conductive layer are buffered, and the adhesion between the amorphous carbon layer and the conductive layer is reinforced. Accordingly, lifting of the amorphous carbon layer for a hard mask caused by differences in the properties between the amorphous carbon layer and the conductive layer can be prevented, leading to an improvement in the stability of a semiconductor device manufacturing process.

Hereinafter, specific embodiments of the present invention will be described in detail with reference to the attached drawings.

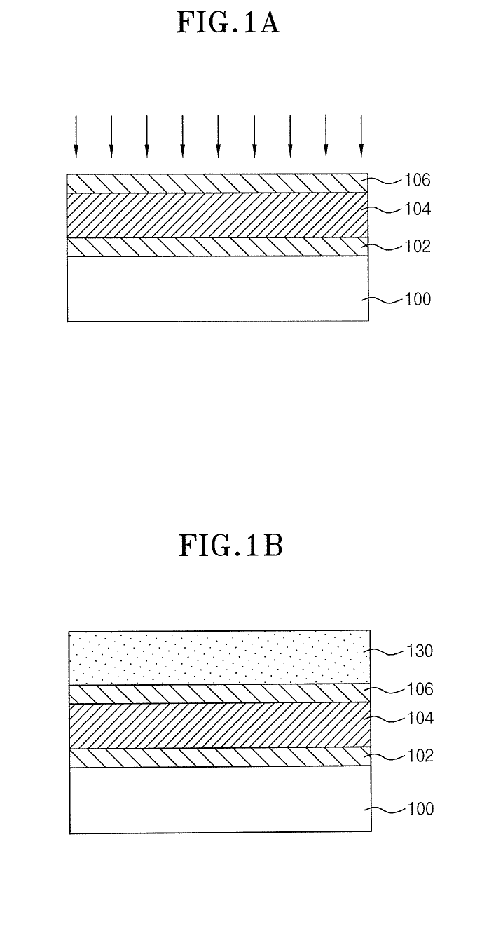

FIGS. 1A and 1B are sectional views shown for explaining a method for manufacturing a semiconductor device capable of preventing lifting of an amorphous carbon layer for a hard mask in accordance with an embodiment of the present invention.

Referring to FIG. 1A, a conductive layer for forming metal lines is formed on a semiconductor substrate 100. The conductive layer comprises a stack of a first barrier layer 102, a metal layer 104 for metal lines, and a second barrier layer 106. The metal layer 104 for metal lines may comprise Al (Aluminum) or W (Tungsten), and the first and second barrier layers 102 and 106 may comprise a stack of Ti/TiN.

As shown in FIG. 1A, the surface of the second barrier layer 106 is treated with plasma using any one or both of an O₂ gas and an Ar gas. The adhesion at the interface between the second barrier layer 106 and a subsequently formed amorphous carbon layer is reinforced by the plasma treatment using the O₂ and/or Ar gases. In particular, in the case where plasma treatment is conducted using an O₂ gas, as O₂ remaining on the second barrier layer 106 forms C—O bonds with the amorphous carbon layer, the adhesion at the interface between the second barrier layer 106 and the amorphous carbon layer is further reinforced.

The second barrier layer 106 may not be required depending upon the manufacturers desired semiconductor device. In this case, the plasma treatment is implemented on the metal layer 104 for metal lines.

Referring to FIG. 1B, an amorphous carbon layer 130 for a hard mask, having properties suitable for a low temperature process of 300˜400° C., is formed on the second barrier layer 106 which is treated with plasma on the surface thereof. The plasma treatment of the second barrier layer 106 and the formation of the amorphous carbon layer 130 for a hard mask is implemented in situ.

Additionally, the plasma treatment using the O₂ and/or Ar gases may also be employed before implementing a process for forming an amorphous carbon layer for a hard mask having properties suitable for a high temperature process of 450˜550° C. in order to reinforce adhesion between the conductive layer and the amorphous carbon layer.

Meanwhile, the adhesion between the amorphous carbon layer for a hard mask and the conductive layer can be reinforced by forming a buffer layer between the amorphous carbon layer and the conductive layer.

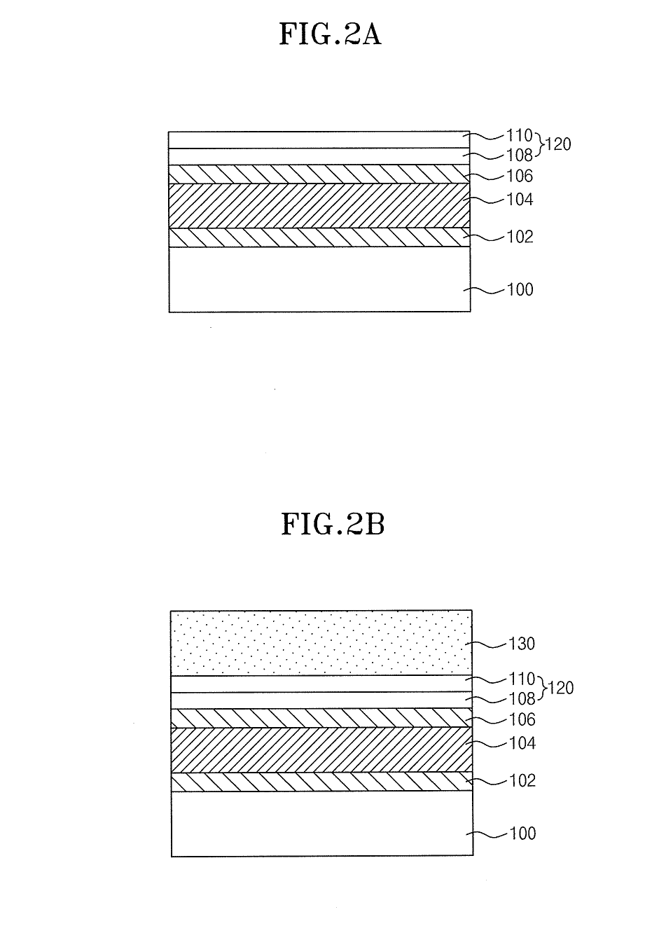

FIGS. 2A and 2B are sectional views explaining a method for manufacturing a semiconductor device capable of preventing lifting of an amorphous carbon layer for a hard mask in accordance with another embodiment of the present invention.

Referring to FIG. 2A a conductive layer for forming metal lines is formed on a semiconductor substrate. The conductive layer comprises a stack of a first barrier layer 102, a metal layer 104 for metal lines, and a second barrier layer 106. The metal layer 104 for metal lines may comprise Al or W, and the first and second barrier layers 102 and 106 may comprise a stack of Ti/TiN.

A buffer layer 120 is formed on the second barrier layer 106 to reinforce adhesion between the conductive layer and a subsequently formed amorphous carbon layer. The buffer layer 120 serves to buffer stresses in the amorphous carbon layer and the second barrier layer 106. The buffer layer 120 comprises an oxide layer 108, a nitride layer 110, or an oxide layer 108/nitride layer 110 stack. The oxide layer 108 comprises an undoped silicate glass (USG) layer having a thickness in the range of 50˜400 Å, and the nitride layer 110 is formed to have a thickness in the range of 50˜200 Å.

The second barrier layer 106 may not be required depending upon the manufacturers desired semiconductor device. In this case, the buffer layer 120 is formed on the metal layer 104 for metal lines.

Referring to FIG. 2B, an amorphous carbon layer 130 for a hard mask, having properties suitable for a low temperature process in the range of 300˜400° C., is formed on the buffer layer 120. The amorphous carbon layer 130 suitable for a low temperature process has a high compression stress; and accordingly if the amorphous carbon layer 130 is formed directly on the second barrier layer 106, the amorphous carbon layer 130 is likely to lift during a subsequent process. Therefore, in an embodiment of the present invention the buffer layer 120 is formed on the interface between the second barrier layer 106 and the amorphous carbon layer 130. As described above the buffer layer may comprise the oxide layer 108 and/or the nitride layer 110 in which a tensile stress or a low compression stress is reduced, and thus the stresses in the second barrier layer 106 and the amorphous carbon layer 130 can be buffered, resulting in the prevention of lifting of the amorphous carbon layer 130.

Moreover, while not shown in the drawings, after implementing plasma pretreatment as shown in FIG. 1B or forming the buffer layer 120 between the second barrier layer 106 and the amorphous carbon layer 130 as shown in FIG. 2B, an anti-reflection layer and a photoresist are formed on the amorphous carbon layer 130, and a patterning process for forming metal lines is implemented.

As is apparent from the above description, in the present invention, by implementing plasma pretreatment or forming a buffer layer on a conductive layer before the formation of an amorphous carbond layer for a hard mask, stresses in the amorphous carbon layer and the conductive layer are buffered, and thus the adhesion between the amorphous carbon layer and the conductive layer can be reinforced. Accordingly, lifting of the hard mask is prevented resulting in improved stability of a semiconductor device manufacturing process.

Although specific embodiments of the present invention have been described for illustrative purposes, those skilled in the art will appreciate that various modifications, additions, and substitutions are possible without departing from the scope and the spirit of the invention as disclosed in the accompanying claims.

What is claimed is:

1. A method for manufacturing a semiconductor device, comprising the steps of:
forming a conductive layer on a semiconductor substrate;
treating a surface of the conductive layer with plasma; and
forming an amorphous carbon layer for a hard mask on the surface of the conductive layer treated by the plasma.

2. The method according to claim 1, wherein the conductive layer comprises Al or W.

3. The method according to claim 1, wherein the conductive layer comprises a barrier layer and the surface of the conductive layer treated with plasma is a surface of the barrier layer.

4. The method according to claim 3, wherein the barrier layer comprises a stack of Ti/TiN.

5. The method according to claim 1, wherein the step of treating the surface of the conductive layer by plasma and the step of forming the amorphous carbon layer are implemented in situ.

6. The method according to claim 1, wherein plasma treatment is implemented using any one or both of an O₂ gas and an Ar gas.

7. A method for manufacturing a semiconductor device, comprising the steps of:
forming a conductive layer on a semiconductor substrate;
forming a buffer layer on the conductive layer; and
forming an amorphous carbon layer for a hard mask on the buffer layer.

8. The method according to claim 7, wherein the conductive layer comprises Al or W.

9. The method according to claim 7, wherein the conductive layer comprises a barrier layer and the buffer layer is formed on the barrier layer.

10. The method according to claim 9, wherein the barrier layer comprises a stack of Ti/TiN.

11. The method according to claim 7, wherein the buffer layer comprises an oxide layer, a nitride layer, or a stack comprising an oxide layer and a nitride layer.

12. The method according to claim 11, wherein the oxide layer comprises an undoped silicate glass (USG) layer.

13. The method according to claim 11, wherein the oxide layer is formed to have a thickness in the range of 50˜400 Å.

14. The method according to claim 11, wherein the nitride layer is formed to have a thickness in the range of 50˜200 Å.
